(19) United States
(12) Patent Application Publication
(10) Pub. No.: US 2024/0265156 A1
(43) Pub. Date: Aug. 8, 2024

(54) METHOD OF MAKING A DIGITAL SPECIFICATION

(71) Applicant: Kepstrum Inc., Vaughan (CA)

(72) Inventor: Payman Kianpour, Markham (CA)

(21) Appl. No.: 18/107,075

(22) Filed: Feb. 8, 2023

(51) Int. Cl. G06F 30/12

(52) U.S. Cl. CPC G06F 30/12

(57) ABSTRACT

A method of generating a digital specification process used for the digitization and graphical representation of a product's design requirements and complex internal and external interactions as a series of signals in what is called a functional profile. This method concurrently represents any number of signals and their interactions, including any number of functional constraints and stress drivers. Using mathematical models in which the digital specification functional profiles are used as inputs, software-based calculation functions capture a product's life under different load profiles with variable and multiple stress factors rather than just a single stress factor.

### FIELD OF THE INVENTION

The present invention relates to reliability analysis and testing processes.

### BACKGROUND OF THE INVENTION

The design and development of new engineered-products involves many steps and levels of involvement and co-operation by various groups within an organization. Engineering organizations are faced with the task of converting real world engineering problems into realized products that solve those problems. Before a product can start to be developed an organization must first determine what they are making, what need does the product they are making intend to meet, and delivers what functions? This need could be explicitly outlined by customers, or implicitly demonstrated in market demands, or the consequence of an organization's own research and development goals, and is often captured in what are called technical specifications or product requirements.

As a result of the rapid change of products in today's global manufacturing industry, experience-based traditional development processes will not provide sufficient and confident results for engineering teams. With new product developments, there is simply a lack of experience, no firm specification, and no time for costly trial & error testing. The presently disclosed platform provides the necessary Digital Transformation solution to empower engineers to adopt model-based development processes, in order to respond to agile shifts in market demand.

Conventional approaches to outlining and managing technical specifications involve managing files in which the main ingredients are words. However, wordy specifications cannot provide a clear image of the complex interactions that will be generated within an engineered product and cannot easily capture the complex load cycles that the product will be subjected to. This can potentially lead to organizations missing important functions that govern the operation and potential failure of their products in the field, leading to recalls. Furthermore, the use of files with wordy and uncorrelated data that must be interpreted and applied by individuals in the product development process leads to ambiguity and a lack of traceability and accessibility in an organization's approach to solving engineering problems; designers can lose sight of the application-level operating stresses, and their effect upon the product's intended performance and stresses.

Product reliability is an important aspect of any product development. Reliability is the probability that a material, component, or system will perform its intended function under defined operating conditions for a specific period of time. Therefore, reliability is the probability that a product will meet its technical specifications that outline said function under said operating conditions for the said period. Therefore, reliability starts from building a foundation of a clear understanding of a product's performance requirements, the complex interactions that will arise from its function, and on being able to integrate those requirements with an understanding of the physics that will govern the product's complex interactions.

The presently disclosed method provides functional profiles made of integrated data points that can accurately visualize the complex interactions that arise from a product's function and furthermore be used as data inputs for a DNA Structured Platform (DSP) to perform mathematical operations and functions on, in order to generate predictive models about the product's real world operational behavior directly from the specifications.

### SUMMARY OF THE INVENTION

The present invention is a method of generating a digital specification as a functional profile, a format made of integrated data points called signals, that accurately visualizes and demonstrates an engineered product's complex interactions and functions, wherein its constituent data points are usable as data inputs for other functions in the present discloser's DNA Structured Platform (DSP) Software, where DNA stands for Design Limit, Nature of Failure, and Actual Life. This application incorporates by reference U.S. Pat. No. 9,612,933.

The (DSP) software is a database structured digital platform meant to elevate and consolidate an organization's knowledge and expertise in dealing with engineering problems. It serves as a platform for product development, production, and life cycle management and is a digital platform that facilitates the implementation of the present discloser's deterministic risk reduction method, hereinafter referred to as Intelligent Reliability Technology (IRT), to allow an organization to: 1) respond to market demands quickly and reliably, 2) reduce costly trial & error, 3) replace a majority of unnecessary tests, 3) establish connectivity between all development, production, and end-of line teams, 4) foster traceability in the organization's development process, 5) empower simulation teams and engineers to identify and solve complex problems, and 6) identify and capture non-deterministic functions that mark the end of a product's deterministic life. The present DSP is a physics-based design platform that is based on using mathematical models to represent every function generated by mechanisms within a product. When the models that accurately represent those functions are developed, the behavior of the component can be determined by the physics that are represented in the closed form equations that model it.

The present DSP is meant to be a platform for documenting applied physics and managing these physics based analytical models to help organizations improve their product development and reliability. Through identifying when a product may be affected by non-deterministic functions, an organization is empowered to invest their resources in both understanding these limits and making more deterministic designs that eliminate the risk of random field failures defined by such non-deterministic functions. In addition to the extensive library of physics models that are accessible to all DSP users, the DSP is meant to facilitate the gathering and application of an organization's knowledge and expertise and turn them into physics based models to help tackle any challenges that the organization's R&D departments may face as they continue to push technological boundaries. The present DSP utilizes the processes disclosed in U.S. Pat. No. 9,612,933, which is incorporated in its entirely in the present disclosure.

A main output of the DSP is product DNA (Design Limit, Nature of Failure, Actual Life), the analytical stress-life model of any component or product, calculated using 3 types of profiles: intent, fault, and limit. When used together as inputs to the DSP's physics based life calculation functions the DSP can accurately determine a product's deterministic life. ‘Intent’ is the operating profile of the product in the ideal and intended operating conditions of the design, assuming all Stress-Drivers are operating at their expected levels. Products often operate in conditions where they are subjected to various stresses at amounts that are greater than the ideal, these are conditions represented in the fault operating profile in which the system receives one or more Stress-Drivers operating outside-intent levels (i.e. temperature is 50° C. as opposed to the intended 30° C.). ‘Limit’ is the operating profile at which the Stress-Drivers of the system cause the KPF of the product to no longer function (i.e. high temperature causing thermal expansion and sudden failure). With these profiles Digital Spec. allows engineers to accurately visualize the variation in product performance under different system environments. By understanding the different system environment profiles, engineers can reveal product weaknesses to implement design changes as necessary.

A product's life represents the highest order of an organization's understanding of the product they're building and the physics based knowledge that represents and governs its operation. In the DNA mapping, the component that is either being modeled or designed on the DSP is defined as the Control Volume (CV). Within the DSP a product's design and then its DNA are generated via a process that begins with generating the digital specification, the present invention.

In order to map the product's DNA, the product requirements/specifications is first digitally captured as digital specification. The present invention provides a method and results of converting product design requirements into digitized multi-signal functional profiles that can at once graphically display a product's intended functions and complex interactions within a system, and be used to generate a product's life model (Product DNA).

The term “functional profile” indicates that the data represented therein is fully integrated with the DSP's other functions and can be used as inputs for mathematical calculations to generate other data used within the DSP software, testing protocols, as well as be related to other profiles, signals, and references.

The present invention's method is carried out within the (DSP) software wherein the product requirements and design intent of a product are converted into a specific format of digital specification. In this method, first the product requirements, which include product functionalities and product performances are identified. Then the product application is identified, which identifies product operating conditions. Then, the relevant performance criteria and possible stress drivers are identified. The relevant performance criteria and possible stress drivers are then converted into a set of signals that reflect parameters that determine product functionalities and product performances. Then a set of intent ranges for the set of signals are identified, wherein the set of desired ranges correspond to a set of product performance parameters and a set of product failure criteria. The visual digital specification is created by overlaying the set of signals on a common time scale. The design intent parameters and stress driver parameters are graphically represented as signals with variable independent y-axis value ranges on a common x-axis time scale and can have independent and different time intervals (delta-t) for their data-points (nodes), and wherein the signals represented are made of correlated data points that can be used as inputs for other mathematical functions in the DSP to generate other data and signals that can then also be overlaid on the initial signal profiles in order to accurately visualize and understand a product's complex interactions and functions.

In order to allow for a seamless transition from conventional development processes to Digital Spec., the engineering team can import product specification and requirement documents into the DSP, through any applicable format (CSV, XLSX, PDF). The engineers can then parse, tag and transform such documents into an accurate visualization of the product's complex functions and interactions. Once the Digital Spec. is created, the engineer can virtually export the profiles to end-of-line test machines in any global facility, directly from the engineer's desk. The Digital Spec. profile can be integrated with existing infrastructure (i.e. using CAE as a virtual test bench to validate results), and provide a more efficient means of communication with stakeholders of the organization (i.e. suppliers and customers).

DSP optimizes product cost and reliability for engineering teams, by consistently digitizing product specification in order to understand its capability in real world operation. By overlaying customer requirements on the product's capability, engineers can respond to customer RFQs (Request for Quotation) in a matter of minutes, thus empowering the engineering teams to continuously seek new market opportunities for their products. Once the capability is determined, the Product DNA is calculated within the DSP using the Intelligent Reliability Methodology, to enable the highest degree of confidence amongst all stakeholders of the organization.

Digital Spec. profiles are the foundation of the DSP's digital twin capabilities. A digital spec profile is the comprehensive and integrated representation of a product as it evolves from the concept stage to an actual product in the field and allows for an integrated view of the entire product lifecycle, thanks to its format and representation of a product as a series of signals, the number of which can be constantly increased, and the values of which adjusted to represent the product in the physical world and model its functions and interactions.

Other advantages over the prior art methods include reduced time to market, reduced costs, minimal long-standing field issues, faster qualification of design changes and shorter test times. Other objects, advantages and novel features of the present invention will become readily apparent from the following drawings and detailed description of preferred embodiments.

### BRIEF DESCRIPTION OF THE DRAWINGS

Embodiments herein will hereinafter be described in conjunction with the appended drawings provided to illustrate and not to limit the scope of the claims, wherein like designations denote like elements.

FIG. 1 shows the high level process of converting product requirements and design intent into a digital specification functional profile.

FIG. 2 shows a more detailed flow diagram showing the considerations made and steps taken in the relevant Submodules in the DSP software to create a product's digital specification.

FIG. 3 describes the steps taken to generate the signals as profiles in the signal analytics submodule, step 609 in FIG. 2.

FIG. 4 shows a car as an example system, to demonstrate how two separate sources of vibration, combine to act as a single vibration stress factor on the control volume (CV), an example electric motor.

FIG. 5 shows an example of a simplified digital spec. graphic profile for an e-pump overlaid on a common time scale (x-axis) 903 in the signal pane 904 of the Signal Analytics Submodule.

FIG. 6 shows an intent profile expanded to include fault and limit profiles, differentiated by stress driver signals like oil contamination.

FIG. 7 describes the difference in a product development process that uses digital specification profiles from a traditional process.

FIG. 8 demonstrates importing product specification and requirement documents into the DSP, through any applicable format (CSV, XLSX, PDF).

FIG. 9. shows the basis of the closed form equations that can be used on the signals within a digital spec.

FIG. 10. Shows DSP's design validation functionalities.

### DETAILED DESCRIPTION

The detailed description of exemplary embodiments of the invention herein makes reference to the accompanying block diagrams and schematic diagrams, which show the exemplary embodiment by way of illustration and its best mode. While these exemplary embodiments are described in sufficient detail to enable those skilled in the art to practice the invention, it should be understood that other embodiments may be realized and that logical and mechanical changes may be made without departing from the spirit and scope of the invention. Thus, the detailed description herein is presented for purposes of illustration only and not of limitation. For example, the steps recited in any of the method or process descriptions may be executed in any order and are not limited to the order presented.

Moreover, it should be appreciated that the particular implementations shown and described herein are illustrative of the invention and its best mode and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various FIGs. Contained herein are intended to represent exemplary functional relationships and/or physical couplings between the various elements. It should be noted that many alternative or additional functional relationships or physical connections may be present in a practical system.

The entirety of this process is meant to be carried out within the DNA Structured Platform (DSP) Software of the present discloser, which has several modules and submodules in which the steps described must be completed. A product's digital specification is eventually represented as what is called an intent profile in the signal analytics submodule.

What follows are the exemplary embodiments of the process that yields this functional profile. For the sake of clarity an example of an electric motor used to drive an electric car is used to demonstrate the steps taken in the process of making a digital specification profile.

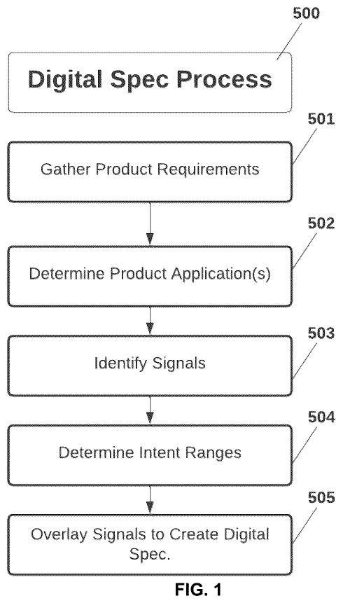

FIG. 1 shows the process of converting product requirements and design intent into a digital specification (Digital Spec.) 500. This process entails a guided method of gathering product requirements, where the desired functionality and the expected product performance are determined 501. Then the product application(s) are determined, through which, the product's operating conditions are identified 502. Then relevant performance criteria and possible stress drivers are identified that will be made into signals, where the parameters that determine such functionality and performance are identified 503. Then, intent ranges for these signals are identified, where the desired values of those performance parameters and failure criteria are quantified 504. Then signal profiles are created by overlaying the signals on a common time scale to create a finalized Digital Specification 505.

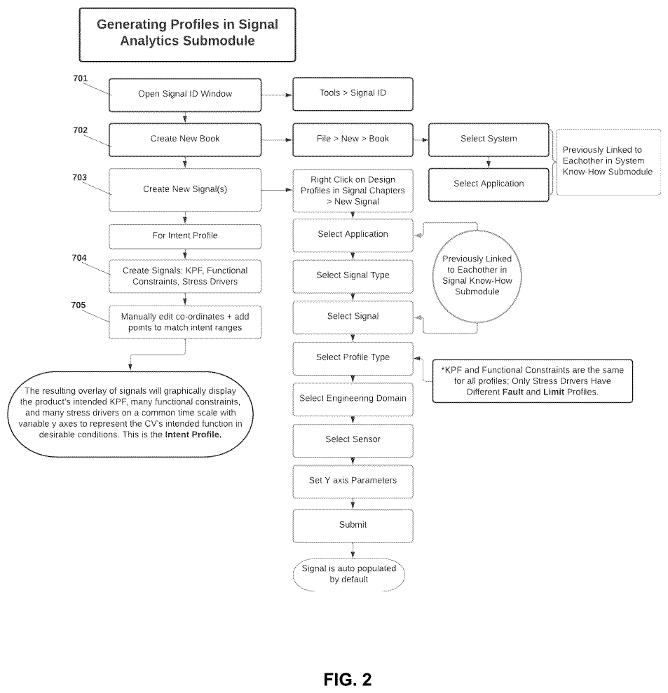

FIG. 2 shows a more detailed flow diagram of this process showing the considerations made and exemplary steps of the method taken in the relevant Submodules in the DSP software to create a product's Digital Spec., identifying the prerequisites for each step of the process and the relevant terminologies related to their completion.

Referring to FIG. 2, in step 601, the product requirements for the product 102 are determined and input into the System Encapsulation Submodule. Product requirements are a series of design parameters or single values that indicate the intended function, expected performance capabilities, and resistances that a product is expected to have. For example, a motor may be intended for use in delivering mechanical power to a car's drivetrain, and it may be expected to deliver at least 5000 RPM at a range of 1-2 Newton meters of Torque, and be able to function in environments with temperatures ranging between −35° C. and 70° C. The process of gathering these requirements yields the definition of the product's KPF (Key Performance Factor), distinguished from any other performance requirements. The present invention defines the KPF as the desired measurable performance that the control volume will deliver. This is determined by choice of the organization, customer, or other relevant stakeholder. In the case of our hypothetical motor, the motor's RPM may be chosen as the KPF while the motor's other intended performance requirements, parameters like output torque, would considered to be among the product's “Functional Constraints” that will be outlined in step 605. If the relevant stakeholders decide that the output torque should be chosen as the KPF, then the RPM would instead be classified as a Functional Constraint.

Step 602 is also meant to be completed in the System Encapsulation Sub Module and involves determining the system within which the control volume (CV) will be mounted in order to define the product's application(s). The product application is defined by the CV size, the system within which the CV is to be mounted, and the CV's intended function within that system. The current invention defines a system as the larger product within which the CV is mounted. In our example of an electric motor where the motor is meant to drive an electric car, the determined system would be a specific car, and the product application would be defined by this intended functionality in this identified car. However, the motor in question may be able to serve the same or another function in a different system, or serve multiple functions within the same system, and potentially be sized differently to deliver those functions, for this reason multiple product applications can be defined for any CV. For instance, the motor could be used to drive the car by directly delivering mechanical power to the drivetrain like in the case of an electric car, or could be used to drive a fuel pump or another component in a gas vehicle. Every different scenario of a particularly sized CV serving a particular function in a particular system represents a different product application.

Once the individual system(s) and application(s) are determined in these Submodules, they are created as data objects (a region of storage that can contain a group of values that is identified by the name given to it in this step) in the static data Submodule 603 by going to that module and creating a new system and a new application. Once these have been defined in the Static Data Submodule the user goes to the System Know-How Submodule to link the “application” and “system” data objects to each other 604. This is done so the defined system(s) and application(s) can be called upon as data containers for use in generating the product's intent profile(s) specific to the intended application later on in step 609.

Once the CV's desired functionality and other performance requirements have been determined the parameters that determine such functionality and performance are identified and defined as signals in the System Models Submodule 605. Signals are variable parameters that represent measurable inputs to or outputs from the CV and from the system. Later in step 609, when signals are created in the Signal Analytics Submodule, they will have particular sets of values that will be identified in step 606. In this step identifying what those values are meant to represent, their “identity”, is a preceding and separate task to quantifying those values. Signals that define and measure the desired output of the CV like RPM and Torque are not the only signals that need to be identified; the variable parameters that measure the various interactions between the CV and the system also need to be identified.

Signals are initially divided into four categories; i) KPF, ii) Functional Constraints (other performance requirements), iii) Stress Driver Controlling Target State, and iv) Stress Drivers Blind to Target state. These signals can be further divided into three types: CV Output Signals, CV input signals, or System Input to CV Signals. All functional constraints should be CV inputs or outputs.

The KPF is always a CV Output Signal, while both kinds of Stress Drivers are always System Input to CV Signals. Stress drivers controlling Target State are inputs from the system that drive or contribute to the function of the CV; without these Stress Drivers acting on the CV it cannot operate and deliver the KPF, but if this stress driver exceeds a certain value it's possible that it could also cause the CV to fail in delivering the KPF. In the case of our electric motor in an electric car this would be the delivered power to the motor from the car battery. Stress Drivers blind to target state are Stress Drivers that are not related to generating the CV output but act on the CV and can also potentially stop the CV from delivering the KPF if they exceed a certain value. These values, whether they are given or determined via calculations later on, are considered part of the failure criteria for the product. Determining the Stress Drivers in a system requires a consideration of interactions between the System and CV and possible environmental factors that can define the state of a system; things like the ambient temperatures and vibration of a system for instance may not be the direct result of the system's operation but nonetheless are also considered to be System Stress Driver inputs to the CV.

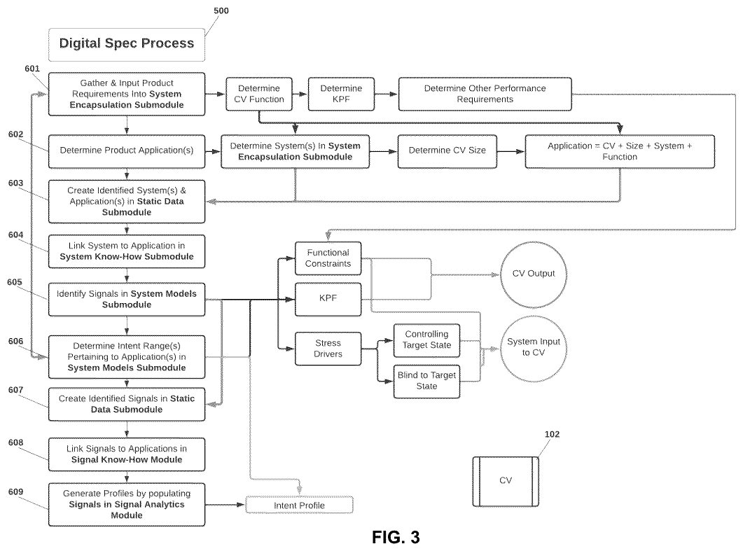

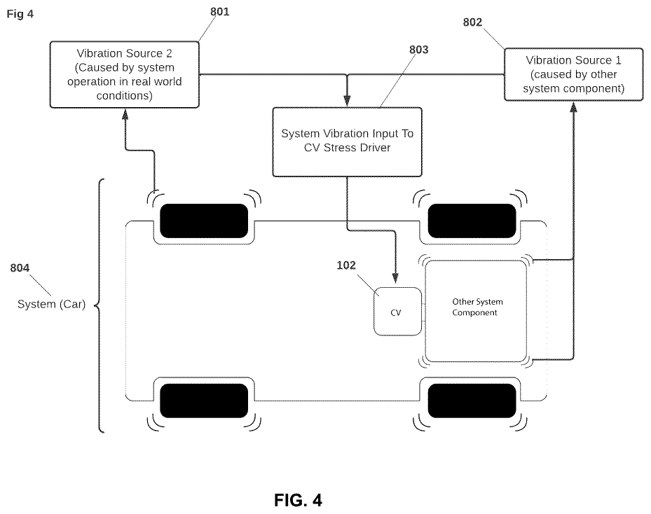

FIG. 3 shows how profiles are generated in the signal analytics module. And FIG. 4 shown an example of vibration in the example car 804, which may be the result of the drivetrain's operation 802 as well as the vibration experienced as a result of the car driving on rough terrain 801 (an example of operation in conditions that results in the whole system vibrating); the accumulated vibration that the CV is subject to 803 is considered to be a System Input to CV Stress Driver (blind to target state).

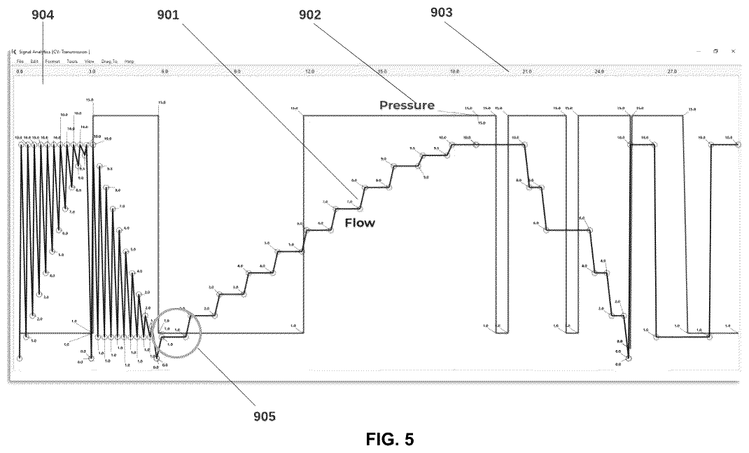

FIG. 5 shows an example of a simplified digital spec. graphic profile made up of two example signals representing the flow 901 and pressure 902 of an e-pump overlaid on a common time scale (x-axis) 903 in the signal pane 904 of the Signal Analytics Submodule. Signals can, and in this case do, have independent y-axes, meaning that the y-values of the signals are different even if they are at the same graphical y-point on the graph. This is visible in this example where the point at which the y-value for the flow signal 901 is 1 is below the point at which the y-value for the pressure signal 902 is 1 905.

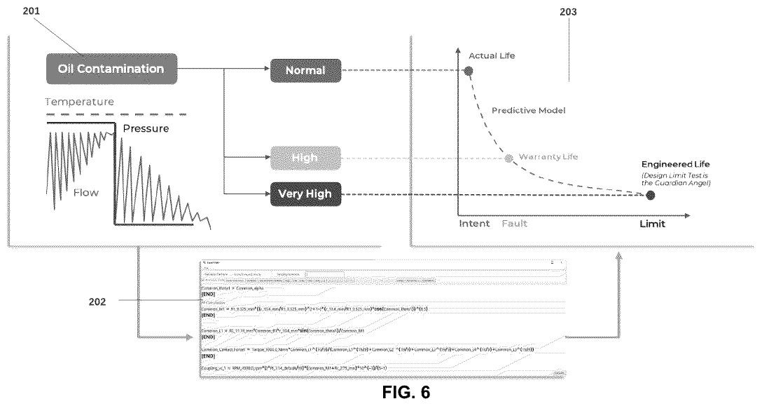

FIG. 6 (for context about the application of the invention) demonstrates how a product's digital specification made of an intent profile can be expanded to include fault and limit profiles, differentiated by stress driver signals like oil contamination 201 having different values that represent the product's operation in operating conditions that are not ideal or intended (fault profile conditions where stress drivers are higher than is intended) or cause the CV to be unable to deliver the KPF or system to break (limit profile conditions where stress drivers are much higher than is intended). The figure shows in simplified form how those profiles are used as inputs to the DSP's calculation functions 202, based on analytical models and closed form equations, to generate the product's predictive stress life model 203. In this predictive stress life model, the y-axis represents time and the product's predicted life span when operating in different conditions described by the intent, fault, and limit profiles, with variable and multiple stress factors, on the x-axis.

Functional Constraints can be either CV outputs or CV input requirements (from the system); whether a Functional Constraint is considered a CV output signal or CV input requirement is dependent on whether the performance requirement is an expected output of the CV, a minimum input it must receive, an expected tolerance the CV must have, or a design limit that the CV should not exceed. In the case of our motor where the RPM is the designated KPF, everything else the design requirements indicate the motor is expected to deliver like torque is a functional constraint; if the requirements indicate something like it should not exceed a certain amount of generated vibration, then that value is also considered a functional constraint and is expressed as a design limit, meaning if the value exceeds the limit the product has failed to deliver the design intent, even if this does not “break” the CV or stop the delivery of the KPF. It should be understood that anything caused by the operation of the CV is considered a Functional Constraint signal. This means vibration caused by the CV itself is not considered a stress driver, even if there is failure criteria associated with the value of this CV generated vibration.

Now that the signals within a system have been defined, their values, expressed as intent ranges, pertaining to the specified application must also be determined in the System Models Submodule 606. These ranges can be specific to the application and can be determined as the result of the data gathering that was undertaken in step 601 for the KPF and Functional Constraint values, as well as any further discussion or deliberation that captures knowable failure criteria for any of the defined Stress Drivers.

Now with the signals defined in their categories and their intent ranges determined they must be created as data objects in the Static Data Submodule 607 before they can be linked to any applications they pertain to in the Signal Know-how Submodule 608 so that they can be used in step 609. Note that here the user also identifies which kind of sensors will be responsible for measuring the values of these signals, an important step for other functionalities in the DSP but not necessary for the process of creating a product's digital spec.

Once the signal, system, and application data objects exist in the Static Data Submodule and are linked to one another in the System Know-how and Signal Know-how Submodules, signal profiles can be generated in the Signal Analytics Submodule. The signals whose relations to a particular application, and whose identity has already been defined, can now be shaped and given the numerical values determined as intent ranges in step 606. FIG. 3 describes this process in further detail. Once overlaid on top of one another the signals defined by the determined intent ranges create an operating profile, called an Intent Profile, that is specific to a given application and is the main output of Digital Spec. This describes the design intent as well as the ideal operating conditions of the CV.

FIG. 3 describes the steps taken within the Signal Analytics Submodule to generate the signals as profiles, step 609 in FIG. 2. Referring to FIG. 3, in the Signal Analytics Submodule the user opens the signal ID window 701, before creating a new Signal Book 702.

Signal Books are groupings of signals as they relate to a specific application. To create a new Signal Book the user clicks on file>new>book then chooses the relevant system and application from the drop down menu. If the user did not complete step 604 and link the system with an application in the System Know-how Submodule then they will be unable to create a new signal book.

Now the user can begin to populate the chosen Signal Book by adding the signals they defined in the Static Data Submodule. Up until this point signals have been data objects defined in static data and only exist as unpopulated containers of number values, with only identity information indicating what those values will represent and in which application(s) (by being linked to the application in Signal Know-how Submodule). The user is now going to pull these signals as data containers into Signal Analytics by right clicking on Design Profiles in the Signal Chapters window and clicking “New Signal”, then filling out the given fields as shown in step 703; The user selects the appropriate application the signal is related to (defined by the signal book they're in), then the signal type (KPF, Functional Constraint, Stress Driver Controlling Target State, Stress Driver Blind to Target State), then selects the signal using a pull down menu (this only displays the signals that were previously linked to the selected application in the Signal Know-how Submodule). The user then chooses the appropriate profile type for the signal; for the KPF and functional constraint signals the correct type is “common” as these are the same for all the intent, fault and limit profiles, while Stress Drivers are unique to each profile type. For the sake of creating the product's digital spec, the user only needs to create the signals for the intent profile (the other profile types, fault and limit, are relevant to other functions of the DSP, but all signals generated for Digital Spec. are part of the common or intent profile types), thus the user should choose the intent profile type for any of the stress driver signals they are shaping. Then the user chooses the engineering domain that the measurable value represented by the signal pertains to (i.e., electrical, fluids, mechanical, chemical, thermal, etc.), then selects a sensor type that will be responsible for measuring the signal's value in the system. Finally, the user sets the y axis parameters for the signal (the maximum and minimum values of the visible y-axis that will be used to show the actual values of the signal, this is specific to each signal and can be changed later). This is a key feature of this kind of digital specification operating profile and the DSP's Signal Analytics Submodule; each individual signal can have its own unique y-axis parameters, allowing for signals with different y-axis value ranges to be displayed on a single graph in order to better understand the relationship of the different signals to one another.

Once the user has filled out these fields and pressed submit, a new signal is generated with a default shape and two node points. The points when selected can be deleted or moved by the user's mouse action, points can be manually added (ctrl+left click), and the coordinates for node points can be manually changed to shape the signals so the resulting signal values match the intent ranges determined in step 606 (specific to the application represented within the current Signal Book). From here the user can continue to create all the KPF, Functional Constraint, and Stress Driver signals with the default shape before manually editing them or they can edit them as they are creating them.

As many signals as are needed can be created, each with their own y-axis parameters. A user can focus on specific signals by hiding individual signals or groups of signals at any point and can then show them again when they are done.

A signal can exist in multiple instances with its data object containing different sets of values within a signal book, called signal iterations. Iterations are used to represent different values for the signals that represent different load cycles the CV may be subjected to and can be created by right clicking on the original signal brought into the signal book and clicking “new iteration”. Creating iterations of the signal with different specific values does not affect the others. Signals can also exist in multiple instances across multiple applications with their data objects containing different sets of values specific to those applications (in different signal books). When the user has shaped all signals in the Intent Profile type, they have finished generating the Intent Profile.

The resulting display of overlaid signals is a functional operating profile that is also called a “Digital Spec.” wherein the product requirements are now digitally displayed as signals on a common x-axis time frame with variable chosen independent y axis ranges that are relevant to the measurement of those individual signals, a simplified example of which can be seen in FIG. 5, where the functional requirements for an example e-pump's oil flow and pressure are overlaid atop one another. A product's Digital Spec. is more than just a graphical display of a product's design requirements, now a user can use the signals in this profile as inputs for the DSP's signal math functions that use physics based models in conjunction with one another, like friction and thermal expansion models, to generate a product's DNA, its Stress Life Model, now with the x-axis being representative of operating conditions differentiated by variations in multiple stress factors.

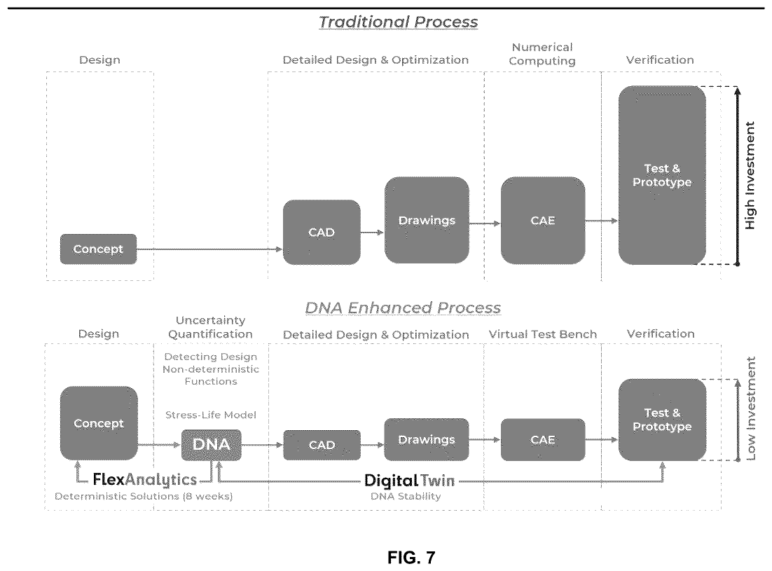

FIG. 7 describes the difference in a product development process that uses digital specification profiles from a traditional process. A product's digital specification is a format of information that can be expanded upon from describing the functional requirements of a CV to including relationships derived from design information that represents the complex functions and interactions of the product. At this stage the digital spec profile can be used to determine whether the design meets the requirements and whether the design has elements that are non-deterministic, in terms of being able to predict behavior or failure, before and during design work allowing for engineering teams to pursue deterministic solutions in the early design and concept phase. The digital spec profile and the stress-life model it generates can be constantly updated to reflect the changes in stress driver conditions, performance, and predicted life as a result of the implemented design changes. Digital spec functional profiles thus can allow engineering teams to inform their design decisions with physics based modelling and validate their designs against the desired functional requirements in real time. This reduces the investment an organization needs to put into the design and optimization, simulation, and traditional verification steps of the product development process.

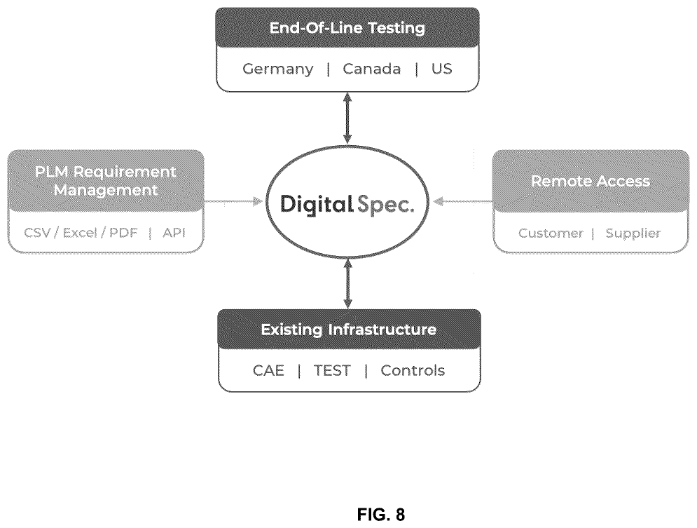

FIG. 8 demonstrates that the present invention allows engineering teams to import product specification and requirement documents into the DSP, through any applicable format (CSV, XLSX, PDF). The engineers can then parse, tag and transform such documents into a digital specification (Digital Spec.) profile to accurately visualize the product's complex functions and interactions. Once the Digital Spec. is created, the engineer can virtually export the profiles to end-of-line test machines in any global facility, directly from the engineer's desk. The Digital Spec. can integrate with existing infrastructure (i.e. using CAE as a virtual test bench to validate results), and provide a more efficient means of communicating information about the product with stakeholders of the organization (i.e. suppliers and customers).

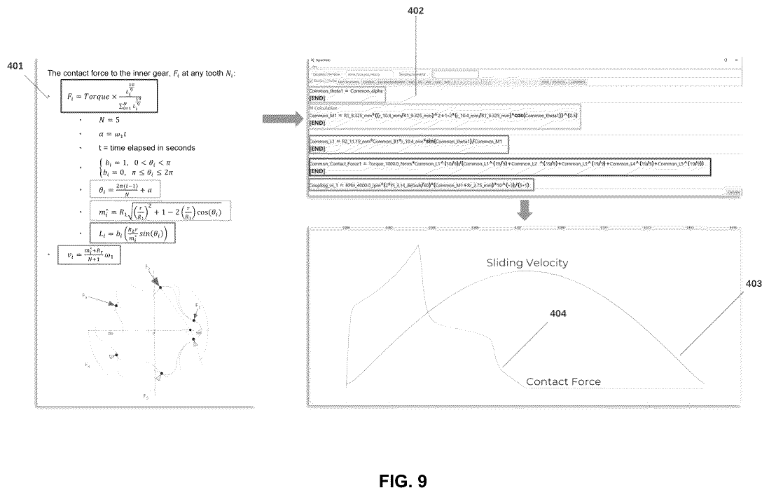

FIG. 9 shows an example of the kinds analytical models 401 that form the basis of the closed form equations 402 that can be used on the signals like sliding velocity portrayed here 403 within a digital spec. profile 404 to calculate the values of other signals 405 whose values are dependent on others like contact force, or to make specific calculations that may be useful to the engineering team, as well as generate stress life models.

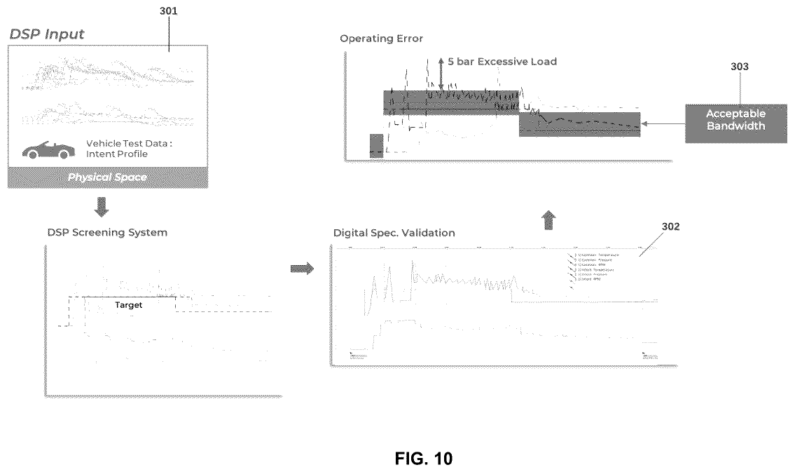

FIG. 10 illustrates the DSP's design validation functionalities wherein live field data 301, test data, or calculated performance data (if the product development is at the design stage prior to physical prototyping/production) can be brought against the Digital Spec. intent profile to validate whether the product performance falls within the tolerance bandwidth 303 (allowable deviation from the spec requirements determined by relevant stakeholders).

What is claimed is:

1. A method of converting a set of functional requirements for a control volume (CV) or a product application into a digital specification, the method comprising steps of:
a) identifying a key performance factor (KPF), a set of functional constraints and a set of stress-drivers;
b) converting the key performance factor (KPF), the set of functional constraints and the set of stress-drivers into a set of signals wherein each signal is described in an x-y plane with an independent y-axis describing a value of the signal and an x-axis being a time scale,
c) creating the digital specification by overlaying the set of signals to form a profile.

2. The method of claim 1, wherein the profile is a design intent profile, a system fault profile or a design limit profile.

3. The method of claim 1, calculating a size and performing a stress life analysis by using the set of signals as inputs in a set of physics based mathematical operations.

4. The method of claim 1, further generating a product DNA, comprising of Design Limit, Nature of Failure, and Actual Life, and a set of design test protocols, wherein the product DNA is generated by real world data gathered from said set of design test protocols and a set of recorded field failures.

5. The method of claim 1, wherein the set of signals comprise of a set of outputs from the control volume (CV) or a set of system inputs to the control volume (CV).

6. A method of converting product requirements and a design intent of a product into a digital specification, the method comprising steps of:
a) determining product requirements comprising of product functionalities and product performances;
b) determining product applications, through which, identifying a set of product operating conditions, and wherein a product application comprises of a control volume (CV) and its size, a system and the CV's function (KPF);
c) identifying relevant performance criteria and a set of stress drivers;
d) identifying relevant performance criteria and possible stress drivers to be converted into a set of signals that reflect parameters that determine product functionalities and product performances;
e) identifying a set of intent ranges for the set of signals, wherein the set of desired ranges correspond to a set of product performance parameters and a set of product failure criteria;
f) defining the signals, systems, and applications as data objects in the static data submodule, which are then linked to one another in the System Know-how Submodule;
g) creating the digital specification by giving the signals values specific to their application and overlaying the set of signals on top of each other on a common time scale,
h) whereby the design intent parameters and stress driver parameters are graphically represented as signals with variable independent y-axis value ranges on a common x-axis time scale and can have independent and different delta-t (time) intervals for their data-points (nodes), and wherein the signals represented are made of correlated data points that can be used as inputs for other mathematical functions in the DSP to generate other data and signals that can then also be overlaid on the initial signal profiles in order to accurately visualize and understand a product's complex interactions and functions.

7. The method of claim 1, further generating a product Design limit, Nature of failure, and Actual life (a product DNA) composed of intent, fault, and limit profiles that together determine a product's deterministic life, wherein the product DNA is generated by applying analytical equations that represent the combined effect of things like friction, wear, thermal expansion, etc. to the functional profiles and using real world data gathered from a set of test protocols as well as from recorded field failures.

8. The method of claim 1, further generating test protocols that are communicated to different test machines, the results of which can be brought back into the DSP to update and/or be compared against the Digital Spec.

9. The method of claim 1, where the digital specification is updated and compared with real world data gathered from recorded field failures, or from live monitoring of products in operation in the field.

10. The method of claim 1, further generating a set of stress life models wherein an x-axis of the stress life model is a multivariable stress factor based on physics based models applied to the profile.
